(19) United States
(12) Patent Application Publication
(10) Pub. No.: US 2020/0191873 A1
(43) Pub. Date: Jun. 18, 2020

(54) BATTERY CAPACITY DISPLAY DEVICE AND BATTERY CAPACITY DISPLAY METHOD

(71) Applicant: Envision AESC Energy Devices Ltd., Sagamihara-shi, Kanagawa (JP)

(72) Inventor: Keisuke YOSHIDA, Sagamihara-shi (JP)

(73) Assignee: Envision AESC Energy Devices Ltd., Sagamihara-shi, Kanagawa (JP)

(21) Appl. No.: 16/349,457

(22) PCT Filed: Oct. 6, 2017
(86) PCT No.: PCT/JP2017/036438

§ 371 Date: May 13, 2019

(30) Foreign Application Priority Data
Nov. 14, 2016 (JP) 2016-221326

(51) Int. Cl. G01R 31/388; G01R 31/367

(52) U.S. Cl. CPC G01R 31/388; G01R 31/367

(57) ABSTRACT

To provide a battery capacity display device capable of performing, in a user comprehensive manner, a display rooted in such a battery characteristic that the battery capacity is closely related to the battery voltage, the battery capacity display device including a battery; a storage part that stores therein a table in which a voltage zone equally dividing a range between a full-charge voltage of the battery and a predetermined voltage is set in association with a battery capacity; a voltage detection part that detects a voltage of the battery; a voltage zone determination part that determines the voltage zone to which the voltage detected by the voltage detection part belongs; a battery capacity determination part that determines the battery capacity from the voltage zone determined by the voltage zone determination part and the table stored in the storage part; and a display part that displays both information related to the voltage zone determined by the voltage zone determination part and information related to the battery capacity determined by the battery capacity determination part.

### TECHNICAL FIELD

The present invention relates to a battery capacity display device used for displaying a dischargeable residual capacity of the battery in an electric device that uses a battery and to a battery capacity display method applied to a display device of an electric device, etc.

### BACKGROUND ART

Some battery-incorporating type electric devices (e.g., battery-incorporating type power storage devices, battery-incorporating type communication devices, and battery-incorporating type mobile devices) have a display part for informing a user of a dischargeable residual capacity of the battery. The user can make preparations for battery exchange or battery charge by referring to such a display part.

For example, Patent Document 1 (JP 2007-327768 A) discloses a battery capacity display device having the following configuration. That is, in a battery residual amount display part 7 composed of three indicators, all the three indicators are lit on when a battery is fully charged, the indicators are lit off one by one with a reduction in battery residual amount, and all the three indicators are lit off when the residual amount becomes zero.

### Patent Document 1: JP 2007-327768 A

### DISCLOSURE OF THE INVENTION

### Problems to be Solved by the Invention

As a method for calculating a battery capacity remaining in the battery (generally, SOC: State of Charge), there are known the following methods: a method of integrating electric power generated with battery charge/discharge; a method of calculating a battery voltage; and a combination thereof. On the other hand, as a method of displaying the calculated battery capacity for a notification, a conventional method of indicating the stages of a battery capacity has still been used. This method provides poor information concerning the battery capacity to users, and the information does not directly reflect battery characteristics.

### Means for Solving the Problems

The present invention has been made to solve the above problem, and a battery capacity display device according to the present invention includes: a battery; a storage part that stores therein a table in which a voltage zone equally dividing a range between a full-charge voltage of the battery and a predetermined voltage is set in association with a battery capacity; a voltage detection part that detects a voltage of the battery; a voltage zone determination part that determines the voltage zone to which the voltage detected by the voltage detection part belongs; a battery capacity determination part that determines the battery capacity from the voltage zone determined by the voltage zone determination part and the table stored in the storage part; and a display part that displays both information related to the voltage zone determined by the voltage zone determination part and information related to the battery capacity determined by the battery capacity determination part.

A battery capacity display method according to the present invention includes: a storage step of storing a table in which a voltage zone equally dividing a range between a full-charge voltage of the battery and a predetermined voltage is set in association with a battery capacity; a voltage detection step of detecting a voltage of the battery; a voltage zone determination step of determining the voltage zone to which the voltage detected by the voltage detection step belongs; a battery capacity determination step of determining the battery capacity from the voltage zone determined in the voltage zone determination step and the table stored in the storage step; and a display step of displaying both information related to the voltage zone determined in the voltage zone determination step and information related to the battery capacity determined in the battery capacity determination step.

### Advantageous Effects of the Invention

The battery capacity display device and battery capacity display method according to the present invention display both the voltage zone determined by the voltage zone determination part (step) and the battery capacity determined by the battery capacity determination part (step). According to the thus configured battery capacity display device and battery capacity display method, it is possible to perform, in a user comprehensive manner, a display rooted in such a battery characteristic that the battery capacity is closely related to the battery voltage to a user.

Further, according to the battery capacity display device and battery capacity display method of the present invention, it is possible to perform a display that makes it easy for a user to grasp that the battery capacity drops at a larger rate than a linear function with a fall in battery voltage.

### BRIEF DESCRIPTION OF THE DRAWINGS

FIG. 1 is a schematic view illustrating the block configuration of a battery capacity display device 1 according to an embodiment of the present invention;

FIG. 2 is a view illustrating an example of a table stored in the storage part 18, in which a voltage zone and a battery capacity are associated with each other;

FIG. 3 is a view illustrating an example of the configuration of a display part 20 in the battery capacity display device 1 according to the embodiment of the present invention;

FIG. 4 is a view illustrating an actual display example displayed on the display part 20;

FIG. 5 is a view illustrating an example of the configuration of the display part 20 in the battery capacity display device 1 according to another embodiment of the present invention; and

FIG. 6 is a view illustrating an example of the configuration of the display part 20 in the battery capacity display device 1 according to still another embodiment of the present invention.

### BEST MODE FOR CARRYING OUT THE INVENTION

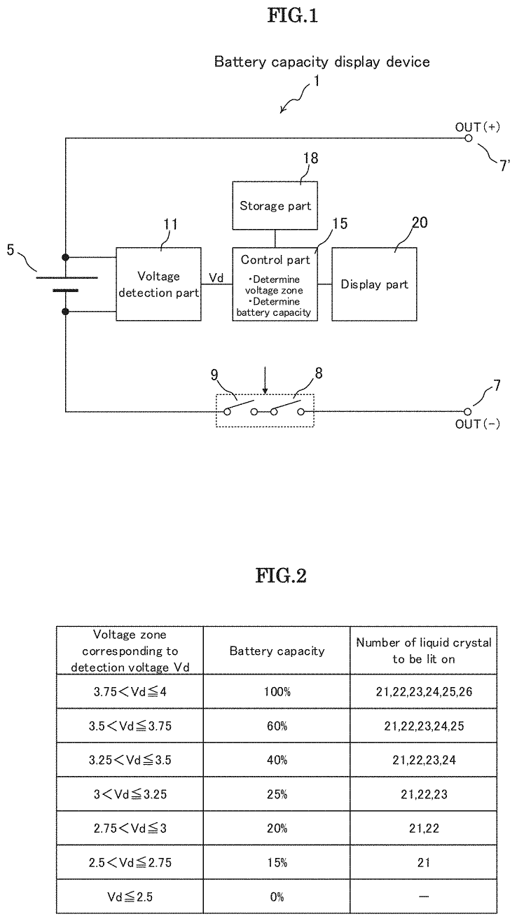

Hereinafter, embodiments of the present invention will be described with reference to the drawings. FIG. 1 is a schematic view illustrating the block configuration of a battery capacity display device 1 according to an embodiment of the present invention. The battery capacity display device 1 is used for informing a user of a residual capacity that a battery 5 can discharge. The battery 5 may be a primary battery or a secondary battery. In the following embodiments, a secondary battery is used as the battery 5.

The battery capacity display device 1 according to the present invention may constitute a part of a battery pack device or a power storage device for feeding power charged in the battery 5 to another device or may constitute a part of a device (communication device, mobile device, etc.) incorporating the battery 5 and consuming power from the battery 5 incorporated therein.

The battery 5 may be a single unit battery, a battery unit obtained by connecting in series a plurality of unit batteries, a battery unit obtained by connecting in parallel a plurality of unit batteries, or a battery unit obtained by combining series-connected and parallel-connected unit batteries.

Power supply terminals 7 and 7′ are provided on a charge/discharge path of the battery 5, and the power of the battery 5 is discharged through the power supply terminals 7 and 7′ or the battery 5 is charged with power therethrough. Further, a charge switch 8 for cutting off the charge path and a discharge switch 9 for cutting off the discharge path are provided on the charge/discharge path of the battery 5. The charge switch 8 or discharge switch 9 is operated based on a control signal from a host controller (not illustrated).

A voltage detection part 11 detects a voltage Vd of the battery 5 and transfers the detected voltage value to a control part 15. The control part 15 receives the detected voltage Vd from the voltage detection part 11 and refers to a table stored in a storage part 18 to thereby perform display control of a display part 20 that displays information concerning at least the residual amount (battery capacity) of the battery 5.

The battery capacity display device 1 according to the present invention is characterized in that to-be-displayed information concerning the residual amount (battery capacity) of the battery 5 is based on only the voltage Vd of the battery 5. That is, when the residual amount (battery capacity) of the battery 5 is to be calculated, information (e.g., temperature) other than the voltage is not used to carry out correction.

The control part 15 may be an arithmetic device such as a general-purpose microcomputer or a dedicated hardware.

The control part 15 corresponds to “voltage zone determination part” and “battery capacity determination part” in claims. Further, the control part 15 executes “voltage zone determination step” and “battery capacity determination step” in claims.

The storage part 18 is a non-volatile memory that the control part 15 can refer to. In the battery capacity display device 1 according to the present invention, the storage part 18 stores therein a table in which at least the voltage zone of the battery 5 and the battery capacity of the battery 5 are associated with each other.

FIG. 2 is a view illustrating an example of the table stored in the storage part 18, in which the voltage zone and the battery capacity are associated with each other.

Here, the “voltage zone” of the battery 5 will be described. The “voltage zone” refers to the band of voltage equally dividing a range between the full-charge voltage of the battery 5 and a predetermined voltage. The predetermined voltage can be set to a voltage at which the residual amount of the battery 5 is completely 0%. The predetermined voltage can be referred to as “discharge termination voltage”.

The following description will be made assuming that the full-charge voltage of the battery 5 is 4 [V] and the predetermined voltage is 2.5 [V]. Further, it is assumed that a range between the full-charge voltage 4 [V] and the predetermined voltage 2.5 [V] is equally divided into six 0.25 voltage zones.

As shown in the left column of the table of FIG. 2, the voltage zone corresponding to a detection voltage Vd detected by the voltage detection part 11 is determined. Further, as shown in the center column of the table of FIG. 2, when the voltage zone corresponding to the detection voltage Vd is determined, the battery capacity corresponding to the determined voltage zone is determined. The display part 20 is used to display both information related to the determined voltage zone and information related to the battery capacity. The number of a liquid crystal part to be lit on on the display part 20 is stored in the right column of the table of FIG. 2.

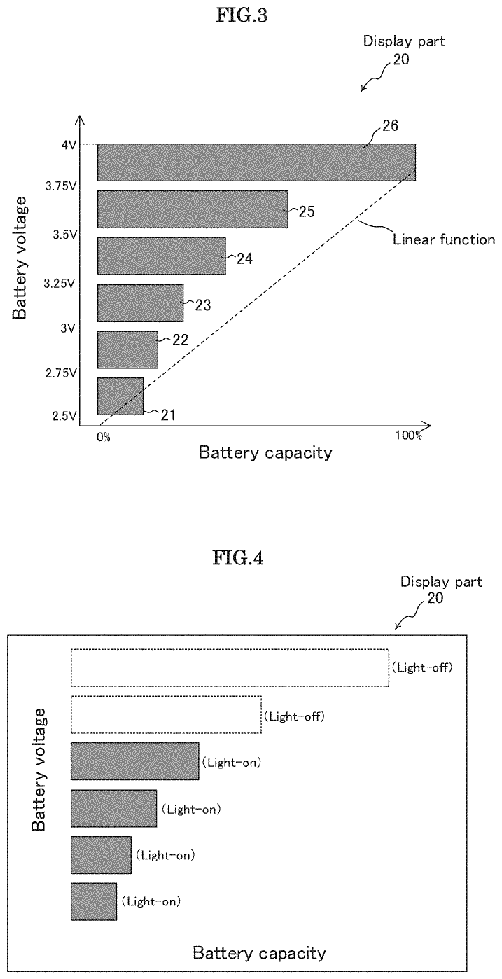

The display part 20 is configured to display both the information related to the voltage zone of the battery 5 and information related to the battery capacity thereof based on a display control instruction from the control part 15. FIG. 3 is a view illustrating an example of the configuration of the display part 20 in the battery capacity display device 1 according to the embodiment of the present invention.

The battery capacity display device 1 according to the present invention is featured in that it displays to which voltage zone the voltage Vd of the battery 5 belongs and how much residual amount (battery capacity) can be expected in the voltage zone. Specifically, the display part 20 two-dimensionally displays both the “voltage zone” and “residual amount (battery capacity)”.

In FIG. 3, the vertical axis represents “voltage zone”, and the horizontal axis represents “residual amount (battery capacity)” (that is, the display part 20 two-dimensionally displays both the “voltage zone” and “residual amount (battery capacity)). Whether or not a concrete numerical value (4 V, 3.75 V, 100%, 0%, etc.) is used to indicate the “voltage zone” and “residual amount (battery capacity)” can be arbitrarily selected by a user.

The display part 20 displays information related to both the “voltage zone” and “residual amount (battery capacity)” by lighting-on/lighting-off of first to sixth liquid crystal parts 21 to 26. Specifically, as the fully-charged battery 5 is discharged toward the termination voltage, the voltage zone reduces, and correspondingly, the sixth liquid crystal part 26 to the first liquid crystal part 21 are sequentially lit off.

Alternatively, a display method may be adopted, in which only the liquid crystal part corresponding to the voltage zone to which the battery 5 belongs is lit on, while the remaining liquid crystal parts are lit off.

In the display part 20 illustrated in FIG. 3, the length or area of each of the first to sixth liquid crystal parts 21 to 26 represents “residual amount (battery capacity)”. Further, the voltage zone corresponding to the liquid crystal part that is located at the highest position of all the liquid crystal parts being lit on represents “voltage zone” to which the battery 5 currently belongs.

FIG. 4 is a view illustrating an actual display example displayed on the display part 20. For example, when the detection voltage Vd of the battery 5 is 3.3 [V], and the voltage Vd belongs to the voltage zone of 3.25 [V]<voltage Vd [V]≤3.5 [V], the first to fourth liquid crystal parts 21 to 24 are lit on, while the fifth and sixth liquid crystal parts 25 and 26 are lit off. At this time, a user confirms the fourth liquid crystal part 24 located at the highest position of all the liquid crystal parts being lit on and can thus recognize that a battery capacity of about 40% is expected as the “residual amount (battery capacity)”.

In the battery capacity display device 1 according to the present invention, for the battery 5 is adopted a display method that can express that the voltage of the battery 5 is lowered from the full-charge state to the termination voltage state and that an expected residual amount (battery capacity) can be almost determined at each voltage level. To this end, the display part 20 is configured to two-dimensionally display both the “voltage zone” and “residual amount (battery capacity)”.

As described above, in the battery capacity display device and battery capacity display method according to the present invention, both the voltage zone determined by the voltage zone determination part (step) and the battery capacity determined by the battery capacity determination part (step) are displayed. Thus, according to the battery capacity display device and battery capacity display method of the present invention, it is possible to perform, in a user comprehensible manner, a display rooted in such a battery characteristic that the battery capacity is closely related to the battery voltage.

Referring back to FIG. 3, the dashed line in FIG. 3 is a line calculated from the relationship between the full-charge voltage and the termination voltage when the relationship between “voltage zone” and “residual amount (battery capacity)” is a linear function. The rightmost positions of the respective second to fifth liquid crystal parts 22 to 25 in FIG. 3 are positioned leftward of the dashed line. That is, when the relationship between “voltage zone” and “residual amount (battery capacity)” is regarded as a function, the lengths of the respective first to sixth liquid crystal parts 21 to 26 in the display part 20 are represented as a function in which the “residual amount (battery capacity)” reduces at a larger rate than the linear function with a reduction in the stage of the “voltage zone”.

The battery 5 has such a characteristic that the battery capacity drops at a larger rate than the linear function with a fall in voltage Vd. The display part 20 according to the present invention expresses this characteristic as well. That is, according to the battery capacity display device and battery capacity display method of the present invention, it is possible to perform a display that makes it easy for a user to grasp that the battery capacity drops at a larger rate than the linear function with a fall in battery voltage.

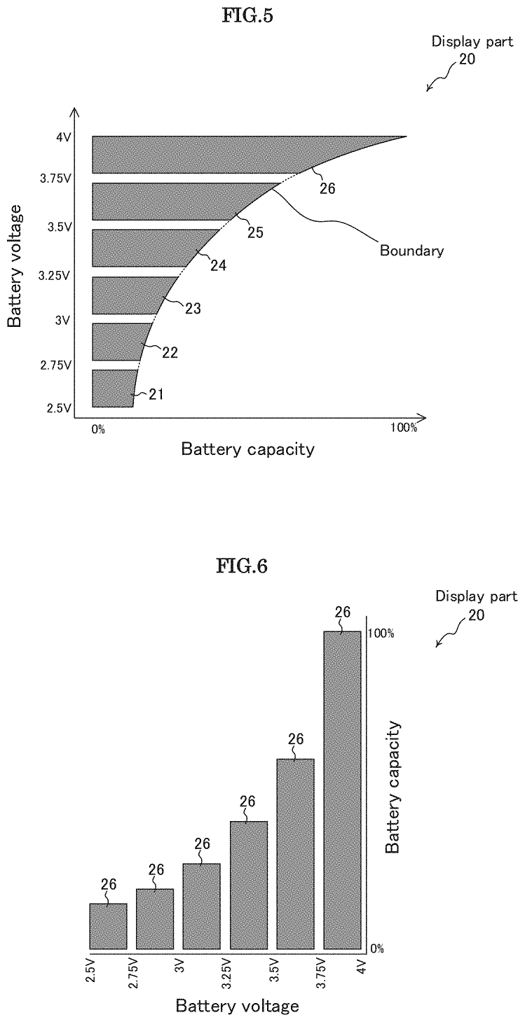

Next, another embodiment of the present invention will be described. FIG. 5 is a view illustrating an example of the configuration of the display part 20 in the battery capacity display device 1 according to the another embodiment of the present invention.

The embodiment illustrated in FIG. 5 differs from the above-described embodiment only in the configuration of the display part 20, so only the different point will be described below.

The embodiment illustrated in FIG. 5 is featured in that the boundary on one side (boundary part on one end portion in the horizontal axis direction) of the first to sixth liquid crystal parts 21 to 26 of the display part 20 is formed of a curved line. This makes it easier for the user to grasp that the battery capacity drops at a larger rate than the linear function with a fall in battery voltage. The curved line substantially corresponds to a curved line based on a quadratic function or an exponential function.

According to the thus configured battery capacity display device and battery capacity display method of the another embodiment, it is possible to perform a display that makes it easy for a user to grasp more accurately that the battery capacity drops at a larger rate than the linear function with a fall in battery voltage.

Next, still another embodiment of the present invention will be described. FIG. 6 is a view illustrating an example of the configuration of the display part 20 in the battery capacity display device 1 according to the still another embodiment of the present invention.

The embodiment illustrated in FIG. 6 differs from the above-described first embodiment only in the configuration of the display part 20, so only the different point will be described below.

In the first embodiment, the vertical axis represents “voltage zone”, and the horizontal axis represents “residual amount (battery capacity)”, while in the embodiment illustrated in FIG. 6, the vertical axis represents “residual amount (battery capacity)”, and the horizontal axis represents “voltage zone”.

As described above, it is possible to adopt various forms as a concrete example of the display form on the display part 20 without departing from the scope of the technical idea of the present invention.

According also to the thus configured battery capacity display device and battery capacity display method of the another embodiment, it is possible to perform, in a user comprehensible manner, a display rooted in such a battery characteristic that the battery capacity is closely related to the battery voltage.

### INDUSTRIAL APPLICABILITY

Some battery-incorporating type electric devices (e.g., battery-incorporating type power storage devices, battery-incorporating type communication devices, and battery-incorporating type mobile devices) have a display part for notifying a user of a dischargeable residual capacity of the battery. The user can make preparations for battery exchange or battery charge by referring to such a display part. However, as a method of displaying the calculated battery capacity for a notification, a method of indicating the stages of a battery capacity has still been used. This method provides poor information concerning the battery capacity to users, and the information does not directly reflect battery characteristics. On the other hand, according to the battery capacity display device and battery capacity display method of the present invention, it is possible to perform, in a user comprehensible manner, a display rooted in such a battery characteristic that the battery capacity is closely related to the battery voltage. Thus, industrial applicability is further enhanced.

### REFERENCE SIGNS LIST

1: Battery capacity display device
5: Battery
7, 7′: Power supply terminal
8: Charge switch
9: Charge switch
11: Voltage detection part
15: Control part
18: Storage part
20: Display part
21: First liquid crystal part
22: Second liquid crystal part
23: Third liquid crystal part
24: Fourth liquid crystal part
25: Fifth liquid crystal part
26: Sixth liquid crystal part

1. A battery capacity display device characterized by comprising:
a battery;
a storage part that stores therein a table in which a voltage zone equally dividing a range between a full-charge voltage of the battery and a predetermined voltage is set in association with a battery capacity;
a voltage detection part that detects a voltage of the battery;
a voltage zone determination part that determines the voltage zone to which the voltage detected by the voltage detection part belongs;
a battery capacity determination part that determines the battery capacity from the voltage zone determined by the voltage zone determination part and the table stored in the storage part; and
a display part that displays both information related to the voltage zone determined by the voltage zone determination part and information related to the battery capacity determined by the battery capacity determination part.

2. The battery capacity display device according to claim 1, characterized in that
the number of the voltage zones is three or more, and
when a relationship between the voltage zone and the battery capacity is regarded as a function, the function is expressed as a function in which the battery capacity drops at a larger rate than a linear function with a reduction in the stage of the voltage zone.

3. The battery capacity display device according to claim 1, characterized in that
the magnitude of the battery capacity is expressed by a length.

4. The battery capacity display device according to claim 1, characterized in that
the magnitude of the battery capacity is expressed by an area.

5. A battery capacity display method characterized by comprising:
a storage step of storing a table in which a voltage zone equally dividing a range between a full-charge voltage of the battery and a predetermined voltage is set in association with a battery capacity;
a voltage detection step of detecting a voltage of the battery;
a voltage zone determination step of determining the voltage zone to which the voltage detected in the voltage detection step belongs;
a battery capacity determination step of determining the battery capacity from the voltage zone determined in the voltage zone determination step and the table stored in the storage step; and
a display step of displaying both information related to the voltage zone determined in the voltage zone determination step and information related to the battery capacity determined in the battery capacity determination step.

6. The battery capacity display method according to claim 5, characterized in that
the number of the voltage zones is three or more, and
when a relationship between the voltage zone and the battery capacity is regarded as a function, the function is expressed as a function in which the battery capacity drops at a larger rate than a linear function with a reduction in the stage of the voltage zone.

7. The battery capacity display method according to claim 5, characterized in that
the magnitude of the battery capacity is expressed by a length.

8. The battery capacity display method according to claim 5, characterized in that
the magnitude of the battery capacity is expressed by an area.

9. The battery capacity display device according to claim 2, characterized in that
the magnitude of the battery capacity is expressed by a length.

10. The battery capacity display device according to claim 2, characterized in that
the magnitude of the battery capacity is expressed by an area.

11. The battery capacity display method according to claim 6, characterized in that
the magnitude of the battery capacity is expressed by a length.

12. The battery capacity display method according to claim 6, characterized in that
the magnitude of the battery capacity is expressed by an area.
